(19) United States
(12) Patent Application Publication
(10) Pub. No.: US 2012/0259568 A1
(43) Pub. Date: Oct. 11, 2012

(54) ELECTRONIC DEVICE WITH BATTERY CAPACITY DETECTING FUNCTION AND BATTERY CAPACITY DETECTING METHOD THEREOF

(75) Inventor: MIN-CHANG CHANG, Tu-Cheng (TW)

(73) Assignee: HON HAI PRECISION INDUSTRY CO., LTD., Tu-Cheng (TW)

(21) Appl. No.: 13/163,721

(22) Filed: Jun. 19, 2011

(30) Foreign Application Priority Data
Apr. 11, 2011 (CN) 201110090268.5

(51) Int. Cl. G01R 31/36; G06F 19/00

(52) U.S. Cl. 702/63

(57) ABSTRACT

An electronic device with a battery capacity detecting function is provided. The electronic device detects an actual voltage of the battery every first preset time interval, calculates a weighted average voltage within a second preset time interval according to all the detected actual voltages within the second preset time interval, and determines a battery capacity according to the calculated weighted average voltage. A method for detecting a battery capacity of an electronic device is also provided.

### BACKGROUND

1. Technical Field

The present disclosure relates to electronic devices, and particularly, to an electronic device having a battery capacity detecting function and a battery capacity detecting method to achieve the function.

2. Description of Related Art

For a conventional electronic device such as a smart phone, a special Integrated Circuit is employed to calculate a remaining battery capacity which is shown on a screen of the electronic device. The special Integrated Circuit may be expensive, thus using the special Integrated Circuit may increase the cost of the electronic device.

### BRIEF DESCRIPTION OF THE DRAWINGS

Many aspects of the present disclosure should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a block diagram of an electronic device in accordance with an exemplary embodiment.

FIG. 2 is a schematic view showing a discharge curve chart of a battery, which records relationship between battery capacity and actual voltages of the battery of the electronic device of FIG. 1.

FIG. 3 is a table showing a relationship between weight and actual voltages of the battery of the electronic device FIG. 1.

FIG. 4 is a flowchart of a method for detecting a battery capacity of the electronic device of FIG. 1, in accordance with an exemplary embodiment.

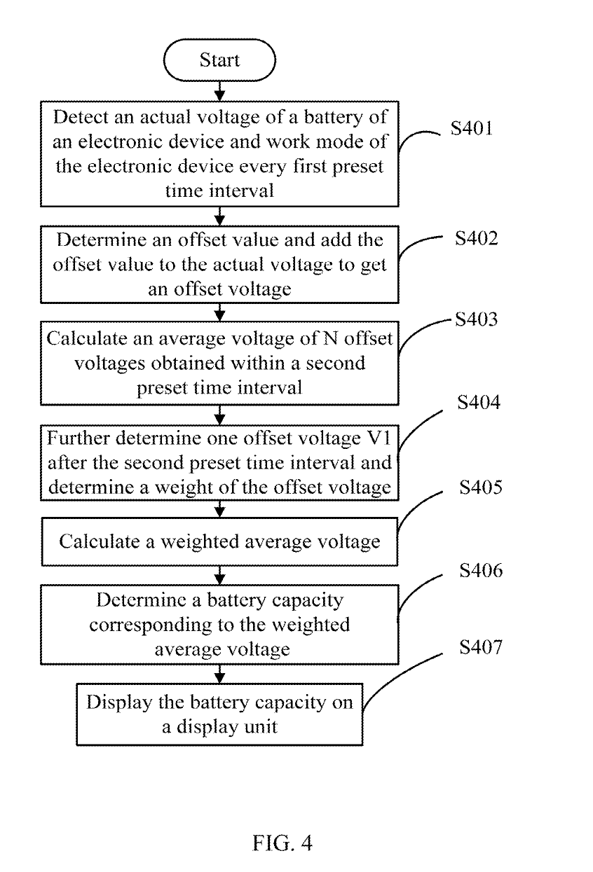

### DETAILED DESCRIPTION

Embodiments of the present disclosure will now be described in detail below, with reference to the accompanying drawings.

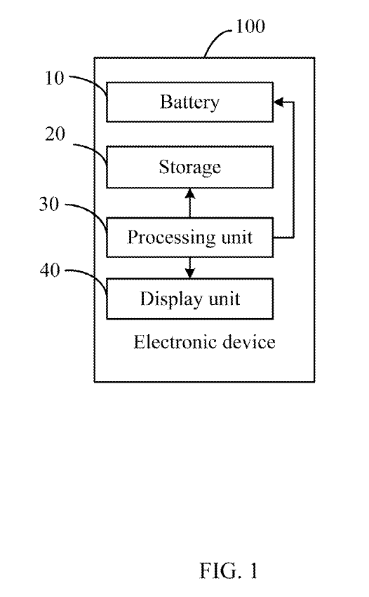

Referring to FIG. 1, an electronic device 100 includes a battery 10, a storage 20, a processing unit 30, and a display unit 40. The battery 10 is configured for supplying power to the electronic device 100. The processing unit 30 is configured for detecting an actual voltage of the battery 10 every first preset time interval, calculating a weighted average voltage within a second preset time interval according to all the detected actual voltages within the second preset time interval, wherein the second preset time interval is an integer times the first preset time interval. The processing unit 30 is further configured for determining a battery capacity according to the calculated weighted average voltage, and displaying the remaining battery capacity on the display unit 40. The detail method for calculating the weighted average voltage will be described below.

The storage 20 stores a first relationship between work modes of the electronic device 100 and offset values. The processing unit 30 detects an actual voltage V of the battery 10 and the work mode of the electronic device 100 every first preset time interval, and determines an offset value corresponding to the detected work mode according to the first relationship, and adds the offset value to the detected actual voltage V to get an offset voltage V1.

The storage 20 further stores a second relationship between offset voltages V1 and their weights, and a third relationship between weighted average voltages V3 and battery capacities. In this embodiment, the weights are obtained by users according to a discharge curve of the battery 10 detected by the user. Each weight reflects a proximity value of each corresponding offset voltage V1 to the actual voltage V of the battery 10. The greater the weight is, the more proximity value of the offset voltage V1 to the actual voltage V of the battery 10.

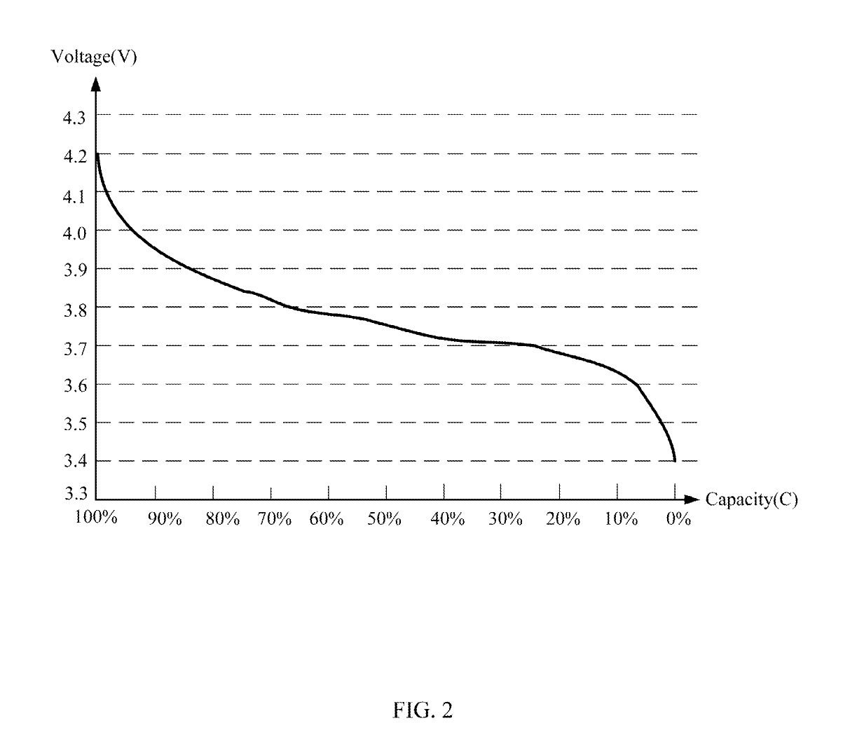

FIG. 2 is a schematic view showing a discharge curve chart of the battery 10, which records a relationship between battery capacity values and actual voltages V of the battery 10. Take a voltage range from 3.4V to 3.6V for example, the curve from the actual voltage 3.4V to 3.6V is relatively precipitous, thus each actual voltage V in this voltage range from 3.4V to 3.6V has a great effect on the battery capacity, and the weight of the offset voltage V1 corresponding to the actual voltage V is greater. The discharge curve from the actual voltages from 3.6V to 3.8V is relatively smooth, thus each actual voltage in this voltage range has a small effect on the battery capacity, and the weight of the offset voltage V1 corresponding to the actual voltage V is relatively less.

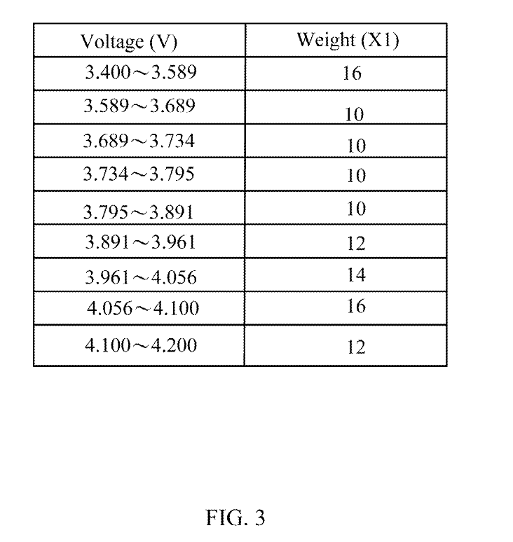

Referring to FIG. 3, in the second relationship, the range of the weight is from 0 to N, wherein N is the times the processing unit 30 detects the actual voltage V within the second preset time interval. In this embodiment, the first preset time interval is preset 10 seconds, and the second preset time interval is 4 minutes, thus the times of the processing unit 30 detects the actual voltage V within 4 minutes is 24 times, and the range of the weight is preset from 0 to 24.

The processing unit 30 further calculates an average voltage V2 of N offset voltages V1 obtained within the second preset time interval.

The processing unit 30 further determines one offset voltage V1 after the second preset time interval, and determines a weight X1 of the offset voltage V1 according to the second relationship. The processing unit 30 calculates the weighted average voltage V3 according to a formula V3=V1*X1/N+V2*(N−X1)/N, and V1 is the offset voltage V1 determined after the second preset time interval, X1 is the weight of the offset voltage V1, V2 is the average voltage V2 obtained within the second time interval.

The processing unit 30 further determines a battery capacity C corresponding to the weighted average voltage V3 according to the third relationship.

FIG. 3 is a flowchart of a method for detecting a battery capacity of an electronic device in accordance with an exemplary embodiment.

In step S401, the processing unit 30 detects an actual voltage V of the battery 10 and the work mode of the electronic device 100 every first preset time interval.

In step S402, the processing unit 30 determines an offset value corresponding to the detected work mode according to the first relationship, and adds the determined offset value to the actual voltage V to get an offset voltage V1.

In step S403, the processing unit 30 calculates an average voltage V2 of N offset voltages V1 obtained within the second preset time interval.

In step S404, the processing unit 30 further determines one offset voltage V1 after the second preset time interval, and determines a weight X1 of the offset voltage V1 according to the second relationship.

In step S405, the processing unit 30 calculates a weighted average voltage V3 according to a formula V3=V1*X1/N+V2*(N−X1)/N, and V1 is the offset voltage V1 obtained after the second preset time interval, X1 is the weight of the offset voltage V1, V2 is the average voltage V2 obtained within the second time interval.

In step S406, the processing unit 30 determines a battery capacity corresponding to the weighted average voltage V3 according to the third relationship between.

In step S407, the processing unit 30 displays the battery capacity on the display unit 40.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. An electronic device comprising:
a display unit;
a battery to supply power to the electronic device;
a storage storing a first relationship between work modes of the electronic device and offset values, a second relationship between offset voltages and their weights, and a third relationship between weighted average voltages and battery capacities; and
a processing unit to detect the work mode of the electronic device and the actual voltage V every first preset time interval, determine an offset value corresponding to the detected work mode according to the first relationship, and add the determined offset value to the detected actual voltage V to obtain an offset voltage V1, calculate an average voltage V2 of N offset voltages V1 within a second preset time interval; the processing unit further to determine an offset voltage V1 after the second preset time interval and determine a weight X1 of the offset voltage V1 determined after the second preset time interval, calculate a weighted average voltage V3 according to a formula V3=V1*X1/N+V2*(N−X1)/N, wherein V1 is the offset voltage V1 obtained after the second preset time interval, X1 is the weight X1 of the offset voltage V1 determined after the second preset time interval, V2 is the average voltage V2 of N offset voltage V1 within the second preset time interval, and determine a battery capacity according to the third relationship, and further display the battery capacity on the display unit.

2. The electronic device as described in claim 1, wherein the second preset time interval is integral times of the first preset time interval.

3. The electronic device as described in claim 1, wherein each of the weights reflects a proximity value of each corresponding offset voltage to the actual voltage of the battery.

4. The electronic device as described in claim 3, wherein the great the weight is, the more proximity value of the offset voltage to the actual voltage of the battery.

5. The electronic device as described in claim 3, wherein the range of the weight is from 0 to N, N is the times the processing unit detects the actual voltage V within the second preset time interval.

6. A method for detecting a battery capacity of an electronic device, wherein the electronic device comprises a battery, and a storage storing a first relationship between work modes of the electronic device and offset values, a second relationship between offset voltages and their weights, and a third relationship between weighted average voltages and battery capacities, the method comprising:
detecting an actual voltage V of the battery and the work mode of the electronic device every a first preset time interval;
determining an offset value corresponding to the first relationship, and adds the determined offset value to the actual voltage V to get an offset voltage V1;
calculating an average voltage V2 of N offset voltages V1 obtained within a second preset time interval;
determining further determines one offset voltage V1 after the second preset time interval, and a weight X1 of the offset voltage V1 according to a second relationship;
calculating a weighted average voltage V3 according to a formula V3=V1*X1/N+V2*(N−X1)/N, wherein V1 is the offset voltage V1 obtained after the second preset time interval, X1 is the weight X1 of the offset voltage V1, V2 is the average voltage V2 of N offset voltage V1 within the second preset time interval;
determining a battery capacity corresponding to the weighted average voltage V3 according to the third relationship;
displaying the battery capacity on the display unit.
